(19) United States
(12) Patent Application Publication
(10) Pub. No.: US 2025/0234495 A1
(43) Pub. Date: Jul. 17, 2025

(54) Container modules and container systems

(71) Applicant: BITMAIN TECHNOLOGIES INC., Beijing (CN)

(72) Inventors: Ketuan Zhan, Beijing (CN); Feng Zhou, Beijing (CN); Tuo Geng, Beijing (CN); Shuangquan Hua, Beijing (CN); Hangkong Hu, Beijing (CN); Fengjie Li, Beijing (CN); Hongshan Zhu, Beijing (CN); Shaoming Huang, Beijing (CN); Zeqin Sun, Beijing (CN); Jinkui Wei, Beijing (CN)

(21) Appl. No.: 19/015,138

(22) Filed: Jan. 9, 2025

(30) Foreign Application Priority Data
Jan. 10, 2024 (CN) 202420064748.7

(51) Int. Cl. H05K 7/20

(52) U.S. Cl. CPC H05K 7/20709; H05K 7/20127

(57) ABSTRACT

The present application relates to the technical field of containers and discloses a container module and a container system. The container module includes at least two box bodies, a first baffle and a second baffle, where the at least two box bodies are provided at intervals, an air inlet and an air outlet are respectively provided at two opposite sides of the box bodies, and the air outlets of two adjacent box bodies are provided opposite each other; the first baffle surrounds the outer periphery of the at least two box bodies, and is configured to prevent hot air from entering areas between the box bodies; the second baffle is provided at the top of the box bodies, and is configured to prevent hot air from impacting the box bodies. The container module of the present application may effectively solve the problem of hot air interference through reasonable layout of the box bodies and setting of the baffles without dispersing the layout of the box bodies, and improves the heat dissipation efficiency of the container module, thereby improving the space utilization rate of the data center site.

### CROSS-REFERENCE TO RELATED APPLICATIONS

This application claims priority to Chinese Patent Application No. 202420064748.7, filed on Jan. 10, 2024 and entitled “CONTAINER MODULE AND CONTAINER SYSTEM”, which is hereby incorporated by reference in its entirety.

### TECHNICAL FIELD

The present application relates to the technical field of containers, and in particular, to a container module and a container system.

### BACKGROUND

An air-cooled data container is a containerization structure similar to a container, and is configured to arrange and manage servers, storage devices, and network devices.

At present, the air-cooled data containers are generally arranged on a vast data center site, and air flow between adjacent data containers is unstable. The devices inside the data containers generate a large amount of heat during operation and interact with each other, easily causing overheating of the devices inside the data containers, thereby affecting the normal operation of the data center.

### SUMMARY

An objective of the present application is to provide a container module, so as to solve the technical problem that devices inside data containers generate a large amount of heat during operation and interact with each other, easily causing overheating of the devices inside the data containers and affecting the normal operation of the data center.

In a first aspect, the present application provides a container module, including:
at least two box bodies, where the at least two box bodies are provided at intervals, an air inlet and an air outlet are respectively provided at two opposite sides of the box body, and the air outlets of two adjacent box bodies are provided opposite each other;
a first baffle, where the first baffle surrounds outer periphery of the at least two box bodies, and is configured to prevent hot air from entering an area between the box bodies: and
a second baffle, where the second baffle is provided at a top of each of the box bodies, and is configured to prevent the hot air from impacting the box bodies.

In an implementation, the container module includes a water curtain structure, where the water curtain structure faces the air inlet of the box body, and is configured to reduce an air intake temperature of the box body.

In an implementation, the water curtain structure is provided at a side of the first baffle away from the box body, and there is a distance between the water curtain structure and the first baffle.

In an implementation, the distance between the water curtain structure and the first baffle is larger than or equal to 1 meter.

In an implementation, the water curtain structure extends upward to the second baffle, and a thickness of the water curtain structure is larger than or equal to 0.1 meters.

In an implementation, the container module includes a dustproof structure, and the dustproof structure is provided between the water curtain structure and the first baffle, and is configured to prevent dust from entering an interior of the box body through the air inlet of the box body.

In an implementation, a distance between the air outlets of two adjacent box bodies is larger than or equal to 6 meters.

In an implementation, the container module includes four box bodies, and the four box bodies are provided at intervals along a transverse direction and a longitudinal direction.

In an implementation, the second baffle is a photovoltaic panel.

In a second aspect, the present application provides a container system including a plurality of the container modules.

The present application provides a container module, which has the following beneficial effects:
for the container module of the present application, the at least two box bodies are provided at intervals to ensure sufficient space between adjacent box bodies, which is conducive to heat dissipation of the box bodies, and also helps to reduce the risk of heat transfer between the box bodies. The air inlet and the air outlet are provided at two opposite sides of the box body, and the air outlets of two adjacent box bodies are provided opposite each other. This layout is conducive to form an appropriate air flow, so that cold air can effectively enter the box bodies, and hot air can be quickly discharged from the box bodies, thereby improving the heat dissipation effect of the box bodies. The first baffle surrounds the outer periphery of the at least two box bodies, and is configured to prevent the hot air from entering areas between each of the box bodies, thereby preventing the hot air from circulating between the box bodies and ensuring that the heat dissipation process of each of the box bodies is relatively independent and is not affected by adjacent box bodies. The second baffle is provided at the top of each of the box bodies, and is configured to prevent the hot air from impacting the box bodies, thereby effectively reducing the direct impact of the hot air on the box bodies, and ensuring that the hot air is guided to the air outlets of the box bodies more effectively. In general, the container module of the present application effectively solves the problem of hot air interference through reasonable layout of the box bodies and setting of the baffles without dispersing the layout of the box bodies, and improves the heat dissipation efficiency of the container module, thereby improving the space utilization rate of the data center site.

### BRIEF DESCRIPTION OF THE DRAWINGS

In order to illustrate the technical solutions in the embodiments of the present application more clearly, a brief introduction will be given to the accompanying drawings required for the description of the embodiments. Obviously, the accompanying drawings in the following description are merely some embodiments of the present application, and for those ordinary skilled in the art, other drawings can also be obtained from these accompanying drawings without creative efforts.

FIG. 1 is a top view of a container module provided by an embodiment of the

present application.

FIG. 2 is a side view of the container module provided by an embodiment of the present application.

FIG. 3 is a front view of the container module provided by an embodiment of the present application.

The reference signs in the drawings are as follows: 10—Box body: 101—Air inlet; 102—Air outlet: 11—First baffle: 12—Second baffle; 13—Water curtain structure: 100—Container module.

### DESCRIPTION OF EMBODIMENTS

The specific implementations of the present application will be further described in detail below in conjunction with the accompanying drawings and embodiments. The following embodiments are merely used to illustrate the present application, but are not intended to limit the scope of the present application.

In the description of the present application, it should be noted that the directional or positional relationships indicated by terms such as “up”, “down”, “front”, “back”, “inside”, and “outside” in the present application are based on the positional relationships shown in the accompanying drawings. These terms are merely intended to facilitate the description of the application and to simplify the description, and are not intended to indicate or imply that the apparatuses and elements referred to must have a specific orientation, be constructed and operated in a particular orientation, and therefore should not be understood as limitations on the present application.

In the description of the present application, it should be understood that terms such as “first” and “second” in the present application are used to describe various information, but the information should not be limited to these terms, and these terms are merely used to distinguish information of the same type from each other. For example, without departing from the scope of the present application, “first” information may also be referred to as “second” information, and similarly, “second” information may also be referred to as “first” information.

In the related technologies, air-cooled data containers cool internal devices by means of air flow: If adjacent data containers are too close to each other, their incoming and outgoing air may intersect with each other, thereby resulting in unstable air flow and affecting cooling effect. Since the devices inside the data containers generate a large amount of heat during operation, in order to prevent the heat from intersecting, the adjacent data containers need to be kept at a certain distance, otherwise the devices are likely to be overheated, thereby affecting the normal operation of a data center. In order to ensure the effective operation of an air-cooling system, sufficient space is required to support free air flow: If the distance between the data containers is too small, the air flow may be obstructed, thereby affecting the overall cooling effect. In order to solve these problems, data center operators usually arrange the data containers in a dispersed manner when arranging them, so as to ensure sufficient spacing and prevent interference with each other between the heat and the air flow. However, this may cause a decrease in the space utilization rate of the data center site, resulting in larger physical areas of data center buildings and increasing cost of infrastructure and operation.

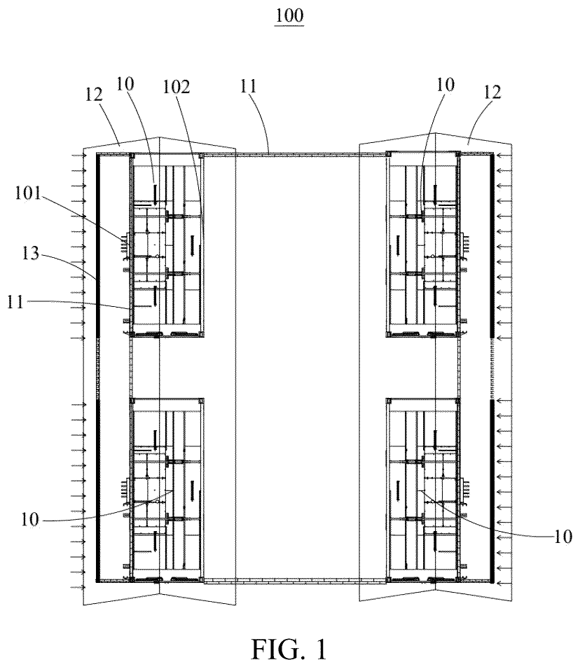

Based on this, as shown in FIG. 1, an embodiment of the present application provides a container module 100, and the container module 100 includes at least two box bodies 10, a first baffle 11, and a second baffle 12, where the at least two box bodies 10 are provided at intervals, an air inlet 101 and an air outlet 102 are respectively provided on two opposite sides of the box body 10, and the air outlets 102 of two adjacent box bodies 10 are provided opposite each other; the first baffle 11 surrounds outer periphery of the at least two box bodies 10, and is configured to prevent hot air from entering an area between each of the box bodies 10; and the second baffle is provided at a top of each of the box bodies 10, and is configured to prevent the hot air from impacting the box bodies 10.

Based on the foregoing technical solutions, in the present embodiment, the at least two box bodies 10 are provided at intervals to ensure sufficient space between adjacent box bodies 10, which is conducive to heat dissipation of the box bodies 10, and also helps to reduce the risk of heat transfer between the box bodies 10. The air inlet 101 and the air outlet 102 are provided at two opposite sides of the box body 10, and the air outlets 102 of two adjacent box bodies 10 are provided opposite to each other. This layout is conducive to form an appropriate air flow; so that cold air can effectively enter the box bodies 10, and hot air can be quickly discharged from the box bodies 10, thereby improving the heat dissipation effect of the box bodies 10. The first baffle 11 surrounds the outer periphery of at least two box bodies 10, and is configured to prevent the hot air from entering areas between the box bodies 10, thereby preventing the hot air from circulating between the box bodies 10 and ensuring that the heat dissipation process of each of the box bodies 10 is relatively independent and is not affected by adjacent box bodies 10. The second baffle 12 is provided at the top of each of the box bodies 10, and is configured to prevent the hot air from impacting the box bodies 10, thereby effectively reducing the direct impact of the hot air on the box bodies 10, and ensuring that the hot air is guided to the air outlets 102 of the box bodies 10 more effectively. In general, the container module 100 in the present embodiment effectively solves the problem of hot air interference through reasonable layout of the box bodies 10 and setting of the baffles without dispersing the layout of the box bodies, and improves the heat dissipation efficiency of the container module 100, thereby improving the space utilization rate of the data center site.

In the present embodiment, there is no restriction on the materials of the first baffle 11 and the second baffle 12, and lightweight, low-cost, and easy to install engineering prefabricated components are mainly used.

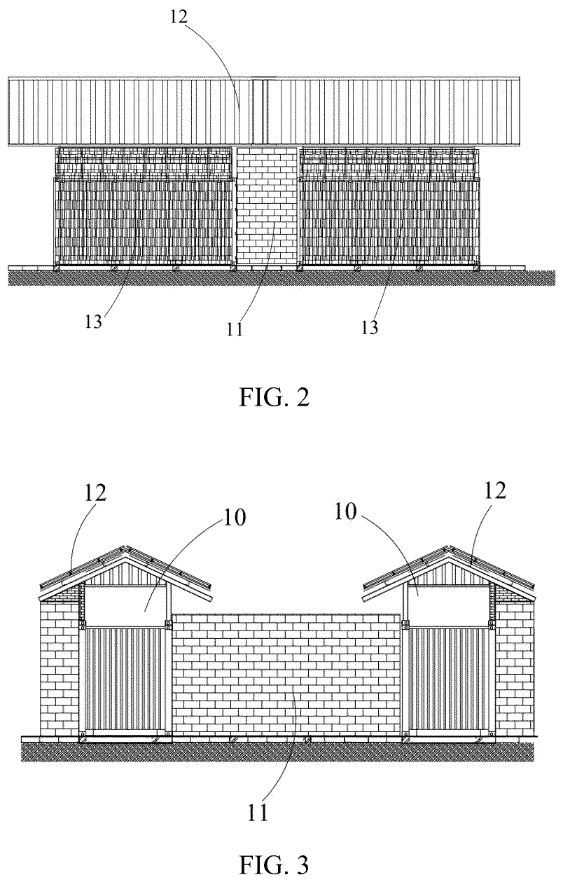

As an implementation, as shown in FIG. 1 and FIG. 2, the container module 100 includes a water curtain structure 13, and the water curtain structure 13 faces the air inlet 101 of the box body 10 and is configured to reduce an air intake temperature of the box body 10.

It should be noted that the water curtain structure 13 is a device for reducing the temperature of the surrounding environment, and generally composed of suspended water droplets or streams, which achieves air temperature regulation through the evaporative cooling effect of the water. Specifically, the water curtain structure 13 faces the air inlet 101 of the box body 10, and when the external air flows through the water curtain structure 13, the water evaporates to absorb the heat, thereby reducing the temperature of the air. This cooling process may affect the air entering the box body 10 through the water curtain structure 13, so as to reduce the temperature of the air at the air inlet 101 of the box body 10. By reducing the temperature of the air at the air inlet 101, the temperature inside the box body 10 can be reduced more effectively, thereby promoting the heat transfer and dissipation. Compared with other cooling systems that require a large amount of energy consumption, using the water curtain structure 13 is a more energy-saving heat dissipation solution, which utilizes the natural evaporation process of water without consuming a large amount of electricity or other energy.

As an implementation, as shown in FIG. 1, the water curtain structure 13 is provided at a side of the first baffle 11 away from the box body 10, and there is a distance between the water curtain structure 13 and the first baffle 11.

Specifically, if the water curtain structure 13 is tightly attached to the box body 10 or is directly affected by the hot air in the box body 10, the water curtain may be blown away by the hot air, thereby reducing the cooling effect. In the present embodiment, a certain distance is provided between the water curtain structure 13 and the first baffle 11, which can reduce this influence and improve the stability of the water curtain structure 13. In addition, the water curtain structure 13 and the first baffle 11 are provided at intervals so as to facilitate air flow, and the air forms a channel between the water curtain structure 13 and the first baffle 11, which can enhance air flow and thus improve the cooling effect.

As an implementation, the distance between the water curtain structure 13 and the first baffle 11 is larger than or equal to 1 meter.

Specifically, the distance between the water curtain structure 13 and the first baffle 11 is larger than or equal to 1 m. Within this distance range, the distance therebetween is large sufficient, so as to ensure that the water curtain structure 13 forms a relative independent cooling system, which is far away from heat sources or other interference factors around the box bodies 10, thereby helping to maintain stability and the cooling effect of the water curtain structure 13. Within this distance range, it helps to optimize air flow and enhance the ability of the water curtain structure 13 to absorb heat during cooling, thereby improving the cooling effect.

As an implementation, as shown in FIG. 2, the water curtain structure 13 extends upward to the second baffle 12, and a thickness of the water curtain structure 13 is larger than or equal to 0.1 meter.

In the present embodiment, the water curtain structure 13 extends to the second baffle 12 at the top of the box body 10, so as to increase the vertical coverage area of the water curtain, which can cover more space and improve the cooling effect of the water curtain structure 13, thereby enabling more air to be cooled through the water curtain.

In the present embodiment, the thickness of the water curtain structure 13 is larger than or equal to 0.1 meter, so that the water curtain structure 13 has sufficient water volume and surface area for evaporative cooling. A thicker water curtain structure 13 generally can provide more water for absorption and evaporation, thereby increasing the cooling effect of the air. Increasing the thickness of the water curtain structure 13 can improve the stability of its structure, which is conductive to maintain the shape and operation of the water curtain, and ensure that the cooling effect thereof can be maintained during the cooling process.

As an implementation, the container module 100 includes a dustproof structure (not shown in the accompanying drawings), the dustproof structure is provided between the water curtain structure 13 and the first baffle 11, and is configured to prevent dust from entering an interior of the box body 10 through the air inlet 101 of the box body 10.

Specifically, in the present embodiment, the dustproof structure is provided in front of the air inlet 101, which can effectively prevent dust from entering the interior of the the box body 10 through the air inlet 101 of the box body 10, thereby keeping the air inside the box bodies 10 clean and prevent the dust from damaging the devices or items inside the box bodies 10. In practical applications, the dustproof structure may be a dustproof mesh.

As an implementation, the distance between the air outlets 102 of two adjacent box bodies 10 is larger than or equal to 6 meter.

Specifically, the air outlet 102 is configured to discharge the hot air inside the box body 10. On the one hand, the present embodiment ensures that there is sufficient distance between the air outlets 102 of two adjacent box bodies 10, which can effectively prevent the hot air from entering another box body 10 from the air outlet 102 of one box body 10. Moreover, there is sufficient space between two adjacent air outlets 102, which can ensure that the hot air can be quickly dissipated to avoid any obstruction in the airflow, thereby avoiding the influence between the two adjacent box bodies 10 and improving the ventilation effect of the container module 100. On the other hand, if the distance between the air outlets 102 of the two box bodies 10 is too small, the hot air at the air outlets 102 of adjacent box bodies 10 may interfere with each other, which affects the air flow and the cooling effect. The distance, which is greater than or equal to 6 meter between the air outlets 102, of the two adjacent box bodies 10 can reduce such influence with each other and maintain system independence of each of the box bodies 10. In general, ensuring that the distance between the air outlets 102 of the two adjacent box bodies 10 is larger than or equal to 6 meter, it can improve the ventilation efficiency of the entire container module 100, so that the hot air can be discharged while avoiding the interference with each other between each of the box bodies 10.

As an implementation, as shown in FIG. 1, the container module 100 includes four box bodies 10, and the four box bodies 10 are provided at intervals in a transverse direction and a longitudinal direction.

Specifically, since the crisscrossing and spacing arrangement of the four box bodies 10, it helps to circulate air between each of the box bodies 10, thereby carrying away the hot air inside the box bodies and improving the ventilation and heat dissipation efficiency of the container module 100. If the four box bodies 10 are densely stacked together, the air cannot be fully circulated between the box bodies 10, thereby resulting in an increase in temperature in the stacking area of the box bodies 10. In general, the transverse and longitudinally spaced box bodies 10 can improve the ventilation and heat dissipation effect of the container module 100, which is beneficial for maintaining a stable internal temperature of the module, preventing heat accumulation, and ensuring the normal operation of the devices inside the box bodies 10.

As an implementation, as shown in FIG. 3, the second baffle 12 is a photovoltaic panel.

Specifically, when the second baffle 12 is the photovoltaic panel, the hot air can be prevented from impacting the box bodies 10 on the one hand, thereby effectively reducing direct impact of the hot air on the box bodies 10. On the other hand, as a roof photovoltaic system, the second baffle 12 can convert solar energy into electric energy, so as to increase the electricity production capacity of the container module 100, thereby helping to meet the power requirements of the data center in daily operation, and reducing the dependence on traditional electricity sources.

According to a second aspect, an embodiment of the present application provides a container system, which includes a plurality of container modules 100.

Specifically, in the present embodiment, the plurality of container modules 100 are combined into the container system, reflecting a concept of modular design. This design can increase flexibility, and facilitate combining different numbers or types of container modules 100 according to actual needs to meet specific function or space requirements. The container modules 100 generally have standard dimensions and structures, and can be quickly stacked, connected or disassembled. Therefore, the container system can be built more quickly, and is applicable to scenarios requiring temporary or movable buildings.

It should be understood that the term “and/or” as used in the description and the appended claims of the present application refers to any combination of one or more of the associated listed items, as well as all possible combinations, and including these combinations. It should be noted that, in this article, the terms “include”, “comprise”, or any other variation thereof are intended to cover non-exclusive inclusion, so that a process, method, item, or system that includes a series of elements not only includes those elements, but also includes other elements that are not explicitly listed, or further includes elements inherent to the process, method, item, or system. Unless further limited, an element defined by the wording “including a . . . ” does not exclude the presence of other identical elements in the process, method, item, or system that includes the element.

The sequence numbers of the above-mentioned embodiments of the present application are only for description, and do not represent the advantages or disadvantages of the embodiments. The above are merely specific embodiments of the present application, but the protection scope of the present application is not limited thereto. Those skilled in the art familiar with the technical field can easily think of various equivalent modifications or replacements within the technical scope disclosed in the present application, and these modifications or replacements should be covered within the protection scope of the present application. Therefore, the protection scope of the present application should be subject to the protection scope of the claims.

1. A container module, comprising:
at least two box bodies, wherein the at least two box bodies are provided at intervals, an air inlet and an air outlet are respectively provided at two opposite sides of the box body, and the air outlets of two adjacent box bodies are provided opposite each other;
a first baffle, wherein the first baffle surrounds outer periphery of the at least two box bodies, and is configured to prevent hot air from entering an area between the box bodies; and
a second baffle, wherein the second baffle is provided at a top of each of the box bodies, and is configured to prevent the hot air from impacting the box bodies.

2. The container module according to claim 1, wherein the container module comprises a water curtain structure, and the water curtain structure faces the air inlet of the box body, and is configured to reduce an air intake temperature of the box body.

3. The container module according to claim 2, wherein the water curtain structure is provided at a side of the first baffle away from the box body, and there is a distance between the water curtain structure and the first baffle.

4. The container module according to claim 3, wherein the distance between the water curtain structure and the first baffle is larger than or equal to 1 meter.

5. The container module according to claim 2, wherein the water curtain structure extends upward to the second baffle and a thickness of the water curtain structure is larger than or equal to 0.1 meters.

6. The container module according to claim 2, wherein the container module comprises a dustproof structure, and the dustproof structure is provided between the water curtain structure and the first baffle, and is configured to prevent dust from entering an interior of the box body through the air inlet of the box body.

7. The container module according to claim 1, wherein a distance between the air outlets of two adjacent box bodies is larger than or equal to 6 meters.

8. The container module according to claim 1, wherein the container module comprises four box bodies, and the four box bodies are provided at intervals along a transverse direction and a longitudinal direction.

9. The container module according to claim 1, wherein the second baffle is a photovoltaic panel.

10. A container system, comprising a plurality of container modules according to claim 1.

11. The container system according to claim 10, wherein the container module comprises a water curtain structure, and the water curtain structure faces the air inlet of the box body, and is configured to reduce an air intake temperature of the box body.

12. The container system according to claim 11, wherein the water curtain structure is provided at a side of the first baffle away from the box body, and there is a distance between the water curtain structure and the first baffle.

13. The container system according to claim 12, wherein the distance between the water curtain structure and the first baffle is larger than or equal to 1 meter.

14. The container system according to claim 11, wherein the water curtain structure extends upward to the second baffle and a thickness of the water curtain structure is larger than or equal to 0.1 meters.

15. The container system according to claim 11, wherein the container module comprises a dustproof structure, and the dustproof structure is provided between the water curtain structure and the first baffle, and is configured to prevent dust from entering an interior of the box body through the air inlet of the box body.

16. The container system according to claim 10, wherein a distance between the air outlets of two adjacent box bodies is larger than or equal to 6 meters.

17. The container system according to claim 10, wherein the container module comprises four box bodies, and the four box bodies are provided at intervals along a transverse direction and a longitudinal direction.

18. The container system according to claim 10, wherein the second baffle is a photovoltaic panel.
